(19) United States
(12) Patent Application Publication
(10) Pub. No.: US 2012/0194977 A1
(43) Pub. Date: Aug. 2, 2012

(54) PORTABLE ELECTRONIC DEVICE

(75) Inventors: Chih-Hsiao Liu, Taoyuan County (TW); Tsung-Ju Chiang, Taoyuan Shien (TW); Li-Ke Chen, Taoyuan County (TW); Chun-Yi Yuan, Taoyuan County (TW)

(73) Assignee: Quanta Computer Inc., Taoyuan Shien (TW)

(21) Appl. No.: 13/193,712

(22) Filed: Jul. 29, 2011

(30) Foreign Application Priority Data
Jan. 31, 2011 (TW) 100103668

(51) Int. Cl. H05K 7/00

(52) U.S. Cl. 361/679.01

(57) ABSTRACT

A portable electronic device includes a main portion, a display portion and a support arm. The main portion has an accommodation area on an upper surface thereof. The support arm is pivotally connected with the main portion at a first end and pivotally connected with the display portion at an opposite second end such that the display portion is rotatable relative to the main portion by means of the support arm. When the display portion is laid against the main portion, the support arm is disposed within the accommodation area.

### RELATED APPLICATIONS

This application claims priority to Taiwan Application Serial Number 100103668, filed Jan. 31, 2011, which is herein incorporated by reference.

### BACKGROUND

1. Field of Invention

The present invention relates to a portable electronic device. More particularly, the present invention relates to a portable computer device.

2. Description of Related Art

The portable computer devices (e.g. notebook computers) are very popular in the market recently and tend to replace the desktop computers. The portable computer devices are equipped with the advantages of smaller volumes, less power consumption and easier portability, thereby satisfying most modern users' demands.

A general-purpose notebook computer consists of a main portion and a display portion. The display portion is pivotally connected with the main portion such that the display portion can be rotated relative to the main portion according to the user's various needs. For example, when the portable computer is turned off, the display portion can be laid against the main portion to be easily portable and packed within a bag. In a general operation, the display portion can be swiveled to a desired angle relative to the main portion.

Although the general-purpose notebook computer is equipped with a display portion with a broad rotation range, the display portion cannot satisfy users' demands in some specific cases. For example, the general-purpose notebook computer would not permit a viewer, who sits opposite to the computer's user, to see the information on a display screen of the display portion without moving the main portion of the notebook computer.

For the forgoing reasons, there is a need for designing a portable computer device to satisfy the above-discussed demands.

### SUMMARY

It is therefore an objective of the present invention to provide an objective to provide a portable electronic device with a flexible angle-adjustment display portion.

In accordance with the foregoing and other objectives of the present invention, a portable electronic device includes a main portion, a display portion and a support arm. The main portion has an accommodation area on an upper surface thereof. The support arm is pivotally connected with the main portion at a first end and pivotally connected with the display portion at an opposite second end such that the display portion is rotatable relative to the main portion by means of the support arm. When the display portion is laid against the main portion, the support arm is disposed within the accommodation area.

According to an embodiment disclosed herein, four corners of the display portion have respective first magnetically-attracting members, and four corners of the main portion have respective second magnetically-attracting members, when the display portion is laid against the main portion, the first magnetically-attracting members attract respective the second magnetically-attracting members so as to secure the display portion to the main portion.

According to another embodiment disclosed herein, either one of the first and second magnetically-attracting members comprises a magnet, the other thereof comprises a magnet or ferromagnetic materials.

According to another embodiment disclosed herein, when the edge of the display portion engages within the positioning slot, a first included angle between the display portion and the main portion ranges from about 30° to about 60°.

According to another embodiment disclosed herein, the main portion includes an input area on the upper surface thereof.

According to another embodiment disclosed herein, the portable electronic device further includes a positioning slot on the upper surface of the main portion, the positioning slot permitting an edge of the display portion to be engaged within, and the positioning slot is disposed at an edge of the input area.

According to another embodiment disclosed herein, the portable electronic device further includes two third magnetically-attracting members disposed along two opposite edges of the input area, and the two third magnetically-attracting members are substantially perpendicular to a long axis of the positioning slot.

According to another embodiment disclosed herein, the support arm is rotatable relative to the main portion by an included angle ranging from about 0° to about 90°.

According to another embodiment disclosed herein, the display portion includes a display screen and an angle-measuring device, a display orientation of the display screen is determined according to a position of display portion measured by the angle-measuring device.

According to another embodiment disclosed herein, the angle-measuring device includes an accelerometer or a Gyro.

Thus, the portable electronic device disclosed herein is equipped with a support arm, which is pivotally connected with the main portion at a first end and pivotally connected with the display portion at an opposite second end such that the display portion is flexibly rotatable relative to the main portion by means of the support arm and the audiences or viewers can sit at any positions around the portable electronic device to view the display screen without moving the main portion of the portable electronic device.

It is to be understood that both the foregoing general description and the following detailed description are by examples, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention. In the drawings,

FIG. 1 illustrates a perspective view of a portable electronic device according to one preferred embodiment of this invention;

FIG. 2 illustrates an exploded view of a portable electronic as illustrated in FIG. 1; and

FIGS. 3A-3C respectively illustrate three using status of a portable electronic device according to one preferred embodiment of this invention.

### DESCRIPTION OF THE PREFERRED EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

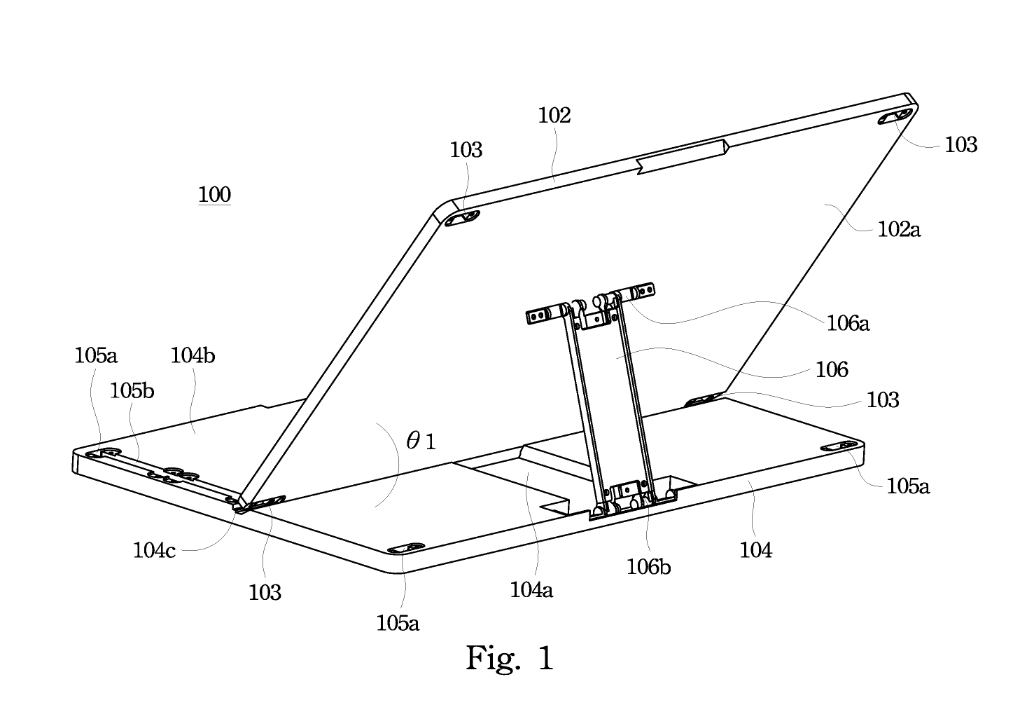

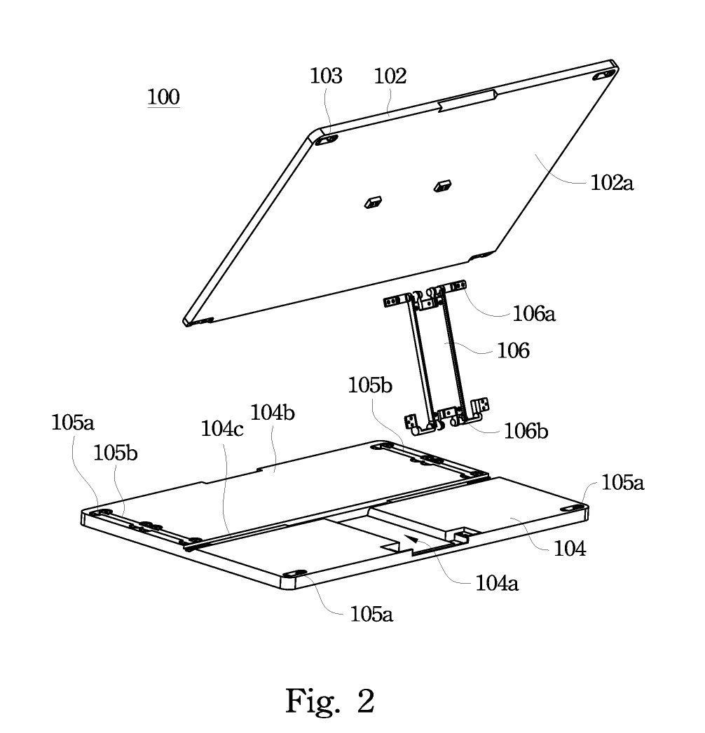

Referring both to FIGS. 1 & 2, FIG. 1 illustrates a perspective view of a portable electronic device according to one preferred embodiment of this invention and FIG. 2 illustrates an exploded view of a portable electronic as illustrated in FIG. 1. A portable electronic device 100 basically includes a main portion 104, a display portion 102 and a support arm 106. Two opposite ends of the support arm 106 are a first hinge member 106a and a second hinge member 106b, respectively. The first hinge member 106a is pivotally connected with a back surface 102a of the display portion 102 and the second hinge member 106b is pivotally connected with a back edge of the main portion 104. The first hinge member 106a and second hinge member 106b both have screw holes, and the display portion 102 and main portion 104 also have screw holes correspondingly for securing the first hinge member 106a and second hinge member 106b to desired positions.

The main portion 104 has an accommodation area 104a on an upper surface thereof for accommodating the support arm 106. When the display portion 102 is laid against the main portion 104, the support arm 106 is located within the accommodation area 104a and sandwiched between the display portion 102 and main portion 104. In this case, a display screen of the display portion 102 is exposed, rather than hidden between the display portion 102 and main portion 104 like in a general-purpose notebook computer.

When the display portion 102 is laid against the main portion 104, the display portion 102 can be secured to the main portion 104 by a magnetic force. As illustrated in FIGS. 1 & 2, four corners of the display portion 102 are equipped with first magnetically-attracting members 103 respectively, and four corners of the main portion 104 are equipped with second magnetically-attracting members 105a respectively. When the display portion 102 is laid against the main portion 104, the first magnetically-attracting members 103 attract respective the second magnetically-attracting members 105a so as to secure the display portion 102 to the main portion 104.

Although the magnetically-attracting members are preferably located at four corners of the main portion and display portion so as to closely secure the display portion 102 to the main portion 104, the magnetically-attracting members are not limited to specific positions of the main portion or display portion. As long as the magnetically-attracting members on the main portion or display portion are located to be attracted each other, their positions are proper in the portable electronic device disclosed herein.

In an embodiment, the first magnetically-attracting member 103 is a magnet while the second magnetically-attracting member 105a is also a magnet. In another embodiment, the first magnetically-attracting member 103 is a magnet while the second magnetically-attracting member 105a is a member made from ferromagnetic materials. In still another embodiment, the first magnetically-attracting member 103 is a member made from ferromagnetic materials while the second magnetically-attracting member 105a is a magnet. That is, either one of the first and second magnetically-attracting members (103, 105a) is a magnet, the other thereof is a magnet or a member made from ferromagnetic materials such that the first magnetically-attracting member 103 and second magnetically-attracting member 105a are able to attract each other.

The main portion 104 has an input area 104b on an upper surface thereof to be designed an input module, e.g. a keyboard, handwriting board, touch pad or touch panel, thereon. The main portion 104 may be equipped with a positioning slot 104c on its upper surface for a bottom edge of the display portion 102 to be engaged into, thereby positioning the display portion 102 in a predetermined angle. The positioning slot 104c is located at an edge of the input area 104b, but not limited to. In an embodiment, when the display portion 102 engages into the positioning slot 104c, an first included angle θ₁ between the display portion 102 and the main portion 104 ranges from about 30° to about 60°, and preferably 45°. In an embodiment, the positioning slot 104c can be equipped with a magnetically-attracting member (not illustrated in the drawings) to attract two first magnetically-attracting members 103 at the bottom edge of the display portion 102, thereby firmly securing the display portion 102 on the main portion 104.

Besides, the main portion 104 may be equipped with two third magnetically-attracting members 105b, which are located along two opposite edges of the input area 104b. The third magnetically-attracting members 105b are to attract two first magnetically-attracting members 103 at the bottom edge of the display portion 102, thereby providing the display portion 102 a flexible positioning range. That is, in addition to engaging the display portion 102 into the positioning slot 104c, users may secure the bottom edge of the display portion 102 to any desired positions of the third magnetically-attracting member 105b to adjust the first included angle θ₁ between the display portion 102 and main portion 104.

In an embodiment, the first magnetically-attracting member 103 is a magnet while the third magnetically-attracting member 105b is also a magnet. In another embodiment, the first magnetically-attracting member 103 is a magnet while the third magnetically-attracting member 105b is a member made from ferromagnetic materials. In still another embodiment, the first magnetically-attracting member 103 is a member made from ferromagnetic materials while the third magnetically-attracting member 105b is a magnet. That is, either one of the first and third magnetically-attracting members (103, 105b) is a magnet, the other thereof is a magnet or a member made from ferromagnetic materials such that the first magnetically-attracting member 103 and third magnetically-attracting member 105b are able to attract each other.

Furthermore, two strip third magnetically-attracting members 105b are arranged substantially perpendicular to a long axis of the positioning slot 104c, but not limited to. The two strip third magnetically-attracting members 105b may be designed on the upper surface of the main portion 104 without the positioning slot 104c designed on the upper surface of the main portion 104. That is, when the main portion 104 is equipped with two strip third magnetically-attracting members 105b, the positioning slot 104c is not essential for positioning the display portion 102. In another embodiment, the main portion 104 is equipped with the positioning slot 104c without two strip third magnetically-attracting members 105b designed on the upper surface of the main portion 104.

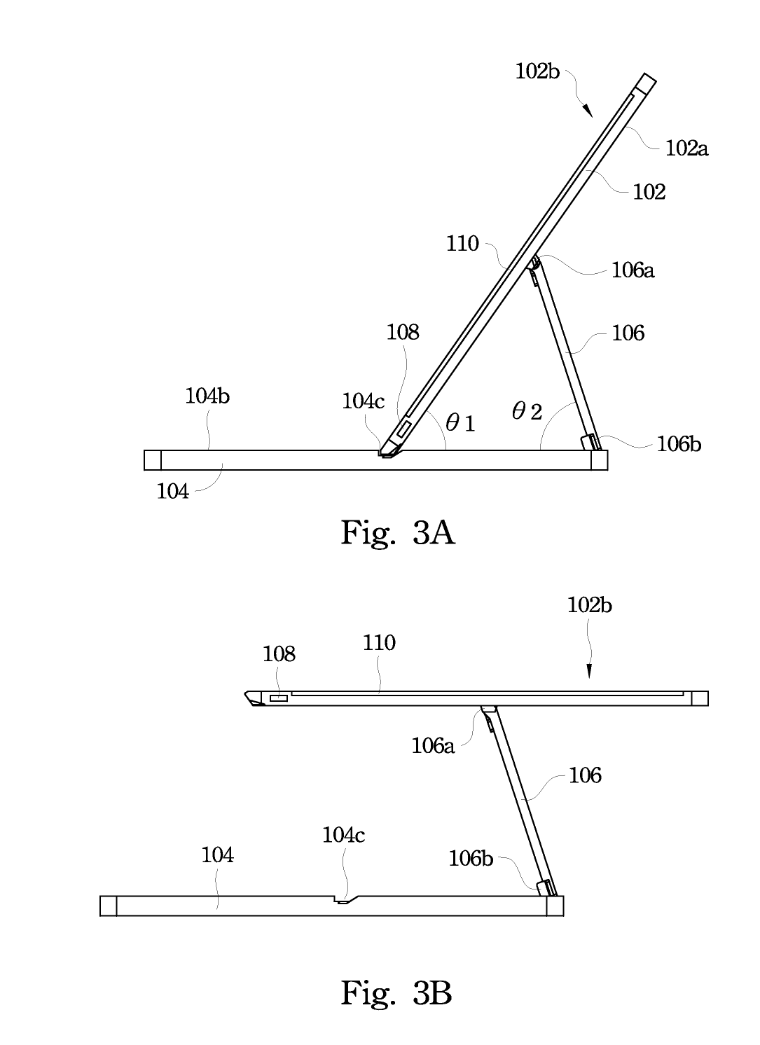

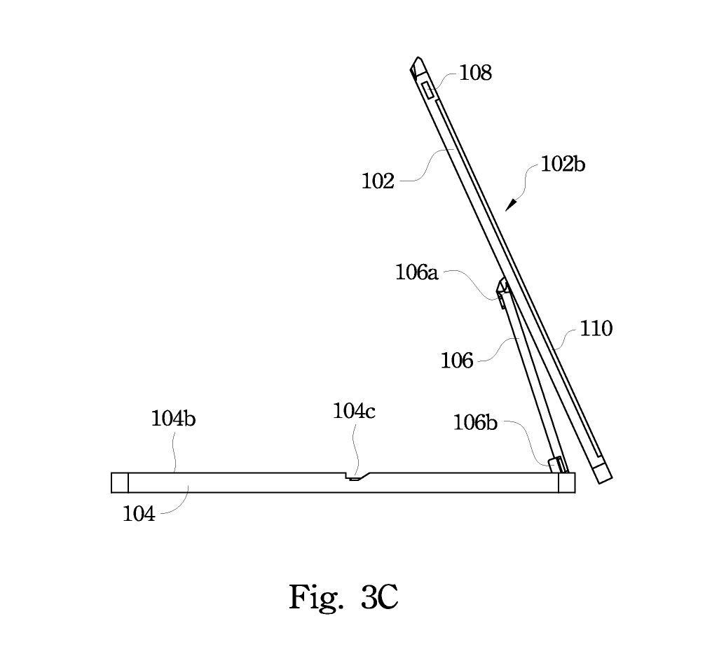

Referring to FIGS. 3A-3C, which respectively illustrate three using status of a portable electronic device according to one preferred embodiment of this invention.

FIG. 3A illustrates a general using mode of the portable electronic device. In this mode, both the display screen 110 (located on a front surface 102b of the display portion 102) and input area 104b of the display portion 102 face the user itself. The bottom edge of the display portion 102 may be positioned by selectively engaging into the positioning slot 104c or by attracting the first magnetically-attracting member 103 and third magnetically-attracting member 105b. Besides, the display portion 102 can be positioned by a torque friction of the first hinge member 106a and second hinge member 106b, rather by engaging into the positioning slot 104c or by a magnetically-attracting force. The display portion 102 may be equipped with an angle-measuring device 108, and a display orientation of the display screen 110 is determined according to a position of the display portion 102 measured by the angle-measuring device 108. In an embodiment, the angle-measuring device 108 can be an accelerometer (e.g. G-sensor) or a gyroscope.

FIG. 3B illustrates a multi-user viewing mode of the portable electronic device. In this mode, the display portion 102 is horizontally positioned with its display screen 110 facing upward for the most audiences around to view. In this case, the display portion 102 can be positioned only by the torque friction of the first hinge member 106a and second hinge member 106b, rather than by engaging into the positioning slot 104c or by a magnetically-attracting force. Because the display portion 102 is horizontally positioned, any display orientation of the display screen 110 may be needed and a manual operation for switching the display orientation is essential. In an embodiment, the manual operation may be implemented by a hotkey on the input area 104b or a virtual hotkey on the display screen 110 to change the display orientation of the display screen 110.

FIG. 3C illustrates another viewing mode of the portable electronic device. In this mode, the input area 104b of the main portion 104 is closer to the user while the display screen 110 faces the audiences or viewers. In this case, the display portion 102 can be positioned only by the torque friction of the first hinge member 106a and second hinge member 106b, rather than by engaging into the positioning slot 104c or by a magnetically-attracting force. The display portion 102 may be equipped with an angle-measuring device 108, and a display orientation of the display screen 110 is determined according to a position of the display portion 102 measured by the angle-measuring device 108. In an embodiment, the display orientations of the display screen 110 in FIG. 3A and FIG. 3C are upside-down as to the display portion 102 such that the audiences or viewers can see the proper display orientation.

In the three above-discussed using mode of the portable electronic device, the support arm 106 is rotatable relative to the main portion 104 by an included angle θ₂ ranging from about 0° to about 90°. Referring to FIG. 3C, when the support arm 106 is rotated relative to the main portion 104 by an included angle greater than 90°, the display portion 102 may hit a support surface such as desktop, which supports the main portion 104. Therefore, the included angle θ₂ ranging from about 0° to about 90° is a preferable range.

According to the above-discussed embodiments, the portable electronic device is equipped with a support arm, which is pivotally connected with the main portion at a first end and pivotally connected with the display portion at an opposite second end such that the display portion is flexibly rotatable relative to the main portion by means of the support arm and the audiences or viewers can sit at any positions around the portable electronic device to view the display screen without moving the main portion of the portable electronic device.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A portable electronic device comprising:
a main portion having an accommodation area on an upper surface thereof;
a display portion; and
a support arm being pivotally connected with the main portion at a first end and pivotally connected with the display portion at an opposite second end such that the display portion is rotatable relative to the main portion by means of the support arm,
when the display portion is laid against the main portion, the support arm is disposed within the accommodation area.

2. The portable electronic device of claim 1, wherein four corners of the display portion have respective first magnetically-attracting members, and four corners of the main portion have respective second magnetically-attracting members, when the display portion is laid against the main portion, the first magnetically-attracting members attract respective the second magnetically-attracting members so as to secure the display portion to the main portion.

3. The portable electronic device of claim 2, wherein either one of the first and second magnetically-attracting members comprises a magnet, the other thereof comprises a magnet or ferromagnetic materials.

4. The portable electronic device of claim 1, wherein the main portion comprises an input area on the upper surface thereof.

5. The portable electronic device of claim 4 further comprising a positioning slot on the upper surface of the main portion, the positioning slot permitting an edge of the display portion to be engaged within, and the positioning slot is disposed at an edge of the input area.

6. The portable electronic device of claim 5, wherein when the edge of the display portion engages within the positioning slot, a first included angle between the display portion and the main portion ranges from about 30° to about 60°.

7. The portable electronic device of claim 4 further comprising two third magnetically-attracting members disposed along two opposite edges of the input area, and the two third magnetically-attracting members are substantially perpendicular to a long axis of the positioning slot.

8. The portable electronic device of claim 1, wherein the support arm is rotatable relative to the main portion by an included angle ranging from about 0° to about 90°.

9. The portable electronic device of claim 1, wherein the display portion comprises a display screen and an angle-measuring device, a display orientation of the display screen is determined according to a position of the display portion measured by the angle-measuring device.

10. The portable electronic device of claim 9, wherein the angle-measuring device comprises an accelerometer or a gyroscope.
